(19) United States
(12) Patent Application Publication
(10) Pub. No.: US 2009/0321248 A1
(43) Pub. Date: Dec. 31, 2009

(54) LOW DAMAGE SPUTTERING SYSTEM AND METHOD

(76) Inventor: Anastasios J. Tousimis, North Bethesda, MD (US)

Correspondence Address: MILES & STOCKBRIDGE PC, 1751 PINNACLE DRIVE, SUITE 500, MCLEAN, VA, 22102-3833, US

(21) Appl. No.: 12/493,969

(22) Filed: Jun. 29, 2009

Related U.S. Application Data
(60) Provisional application No. 61/076,950, filed on Jun. 30, 2008.

(51) Int. Cl. C23C 14/35

(52) U.S. Cl. 204/192.12; 204/298.19; 204/298.17

(57) ABSTRACT

A sputtering system includes a disk-shaped target concentric with an annular anode in a reaction chamber. A thermally-sensitive sample is arranged in the reaction chamber so as to receive material sputtered from the target. The thermally-sensitive sample can be a soft tissue biological specimen. A magnet is arranged proximal to the sample within the reaction chamber. The magnet can be a U-shaped magnet or one or more bar magnets. During sputtering from the target, the magnetic field of the magnet deflects the trajectory of secondary electrons generated by the sputtering process, thereby protecting the sample from heating and damage.

### CROSS REFERENCE TO RELATED APPLICATIONS

This application claims the benefit of U.S. Provisional Application No. 61/076,950, filed Jun. 30, 2008, which is incorporated by reference herein in its entirety.

### FIELD

The present application relates generally to sputtering systems and methods and, more particularly, to systems and methods for low damage sputtering of a material onto a sample.

### BACKGROUND

Sputtering has developed into a convenient method for thin film deposition for a variety of applications. Traditionally-employed in the semiconductor industry, it has primarily been used to deposit thin films of metals onto a substrate for making electrical connections. The conformal nature of the sputtering system (i.e., lack of a shadowing effect) has made it a fundamental system for the development of microelectromechanical system (MEMS) and other 3-D microstructures. Sputtering has also found application to materials outside of the traditional semiconductor realm. For example, sputtering is used in industry for application of films to compact discs, computer disks, and active-matrix liquid crystal displays (LCD). The application of sputtering is also not limited to electronics, as various tools and mechanical components, such as bearing gears and saw blades, have been coated with sputtered films for wear-resistance.

A simplified diagram of a conventional sputtering system is shown in FIG. 1. A reaction chamber 102P has a cathode 106P located at one end of the chamber. Located opposite to the cathode 106P at the opposite end of the reaction chamber 102P is an anode 108P, supporting thereon a substrate 110P to be coated. The interior volume 116P of the reaction chamber 102P is evacuated through vacuum connection 112 to a reduced pressure. The interior volume 116P of reaction chamber 102P is then filled with a gas, such as nitrogen, argon, or xenon, at low pressure through gas input line 114. Such pressures may typically range from 0.001 to 1 Torr. Attached to (or integrated with) the cathode is a target 104P of material to be sputtered onto a substrate 110P. A high negative potential (e.g., between −500V and −2 kV) is applied to cathode 106P. As a result of the high field strength between the cathode 106P and anode 108P, free electrons in the reaction chamber interior 116P are accelerated and impact the gas atoms. The transfer of kinetic energy between the accelerated free electrons and the gas atoms causes ionization of each gas atom into a secondary free electron and a positive ion. The secondary free electrons are also capable of being accelerated by the existing electric field to thereby generate additional free electron-ion pairs. The resulting avalanche of ions and electrons results in breakdown of the gas and the generation of a plasma. Upon recombination of a free electron with a positive ion, a photon is released, resulting in the characteristic glow of the plasma. Positive ions are accelerated toward the target 104P by the existing electric field. The impact of the ions with the target 104P causes surface atoms to be ejected by momentum transfer. These surface atoms are primarily neutral atoms and thus are not affected by the existing electric field. Some of these surface atoms are ejected in the direction of the substrate 110P, where, upon contact, they become deposited on the substrate's surface.

Although sputtering may be considered a relatively low temperature process as compared to other material deposition processes, a considerable amount of energy is dissipated at the target and sample surfaces. Only 1% of the energy actually goes into the sputtering operation while 75% of the energy in the sputtering system is dissipated at the target. The remaining 24% of the energy is dissipated by secondary electron bombardment of the substrate. While some semiconductor and/or metal substrates may be able to withstand moderate heating caused by this secondary electron bombardment, some specimens may be especially vulnerable to damage from these secondary electrons, for example, by surface damage or heating. Such specimens can include thermally sensitive samples, such as soft tissue biological samples. Coating of soft tissue biological samples can be particularly useful for examination, tagging, imaging or other investigational methods. Such biological samples may include, but are not limited to, cancer cells, bacteria, viruses, or tissues samples. However, for these biological samples, heating about 55° C., can irreversibly damage these samples. Above 55° C., the cellular membrane of biological specimens may be subject to thermal denaturing and/or melting, thereby rendering the sample unsuitable for further study.

Magnetrons have been used in connection with sputtering systems to help confine electron trajectories to the vicinity around the target. Thus, the free electrons should not bombard the substrate to the same extent as without the magnetron. However, such systems are complex and add a significant cost to conventional sputtering systems. In addition, the location of the magnetron apparatus external to the reaction chamber requires a high magnetic field, which may not afford complete protection to the substrate from secondary electron bombardment.

Accordingly, there is a need in the art for a simple sputtering system and method that minimizes heating and electron bombardment of a sample. There is further a need in the art for a sputtering system that minimizes substrate heating and surface bombardment so as to allow for sputtering of a sensitive substrate. Additionally, there is a need in the art for a sputtering system that can be used for sputtering of a soft tissue biological sample without resulting in thermal denaturing and/or melting of the sample.

Embodiments described herein may address the above-mentioned problems and limitations, among other things.

### BRIEF DESCRIPTION OF THE DRAWINGS

Embodiments will hereinafter be described in detail with reference to the accompanying drawings, wherein like reference numerals represent like elements. The drawings have not been drawn to scale.

FIG. 1 is a schematic diagram of a conventional sputtering system.

FIG. 2A is a schematic diagram of a sputtering system according to a first embodiment of the present disclosure.

FIG. 2B is a cross-sectional view of FIG. 2A showing an arrangement for the cathode and the anode of the sputtering system.

FIG. 3 is an isometric view of a magnet for use in a sputtering system according to one or more embodiments of the present disclosure.

FIG. 4A is a schematic diagram of the sputtering system of FIG. 2A showing a sample of electric and magnetic field lines during a sputtering operation.

FIG. 4B is a schematic diagram of the sputtering system of FIG. 2A showing plasma formation during a sputtering operation.

FIG. 5A is a schematic diagram showing location of temperature readings along a center line of the magnet in the sputtering system of FIG. 2A during a sputtering operation.

FIG. 5B is a schematic diagram showing location of temperature readings along a top plane of the magnet in the sputtering system of FIG. 2A during a sputtering operation.

FIG. 6 is a schematic diagram of a sputtering system according to a second embodiment of the present disclosure.

FIG. 7A is a schematic diagram of the sputtering system of FIG. 6 showing a sample of electric and magnetic field lines during a sputtering operation.

FIG. 7B is a schematic diagram of the sputtering system of FIG. 6 showing plasma formation during a sputtering operation.

FIG. 8 is a schematic diagram showing location of temperature readings in the sputtering system of FIG. 6 during a sputtering operation.

FIG. 9 is a schematic diagram of a sputtering system according to a third embodiment of the present disclosure.

FIG. 10 is a schematic diagram of the sputtering system of FIG. 9 showing a sample of electric and magnetic field lines during a sputtering operation.

FIG. 11 is a schematic diagram of a sputtering system according to a fourth embodiment of the present disclosure.

FIG. 12 is a schematic diagram of the sputtering system of FIG. 11 showing a sample of electric and magnetic field lines during a sputtering operation.

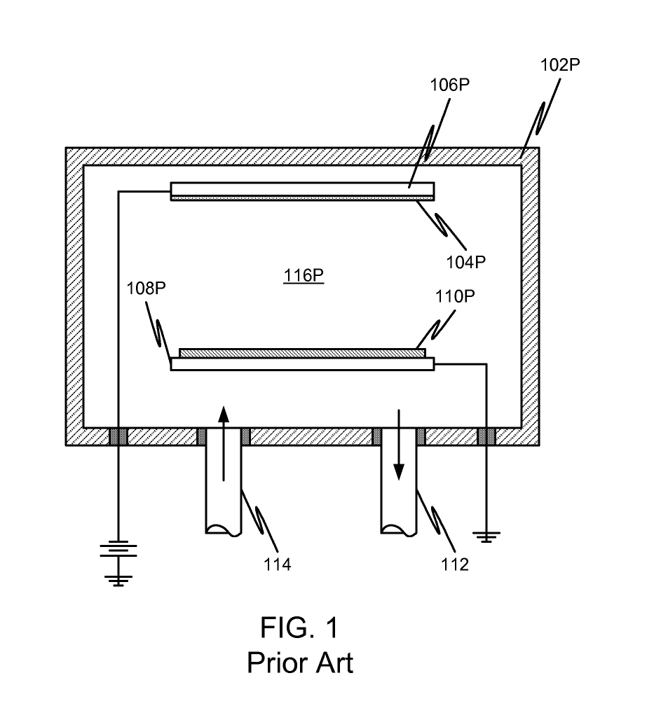

### DETAILED DESCRIPTION

In general, embodiments of the present disclosure are directed to low damage sputtering systems and methods. A sputtering system can include a target and an anode in a reaction chamber. The reaction chamber is evacuated and then filled with a low pressure pure gas. Application of an appropriate voltage between the target and the anode results in plasma formation within the reaction chamber. Ions from the plasma interact with the target to cause sputtering of surface atoms therefrom onto a sample. The sample may be a thermally-sensitive sample. A magnet is arranged in the reaction chamber proximal to the sample such that the magnetic field of the magnet deflects secondary electrons from the plasma away from the sample, thereby reducing and/or minimizing surface heating and damage cause by secondary electron impact on the sample.

Embodiments of the present disclosure are particularly advantageous with regard to the coating of soft tissue biological specimens, which may be subject to microscopic damage by conventional sputtering systems. By providing a magnet within the interior of the reaction chamber proximal to the sample, the temperatures of the sample can be reduced as compared to sputtering without the magnet, thereby preventing thermal denaturing of biological samples or damage to other thermally sensitive substrates.

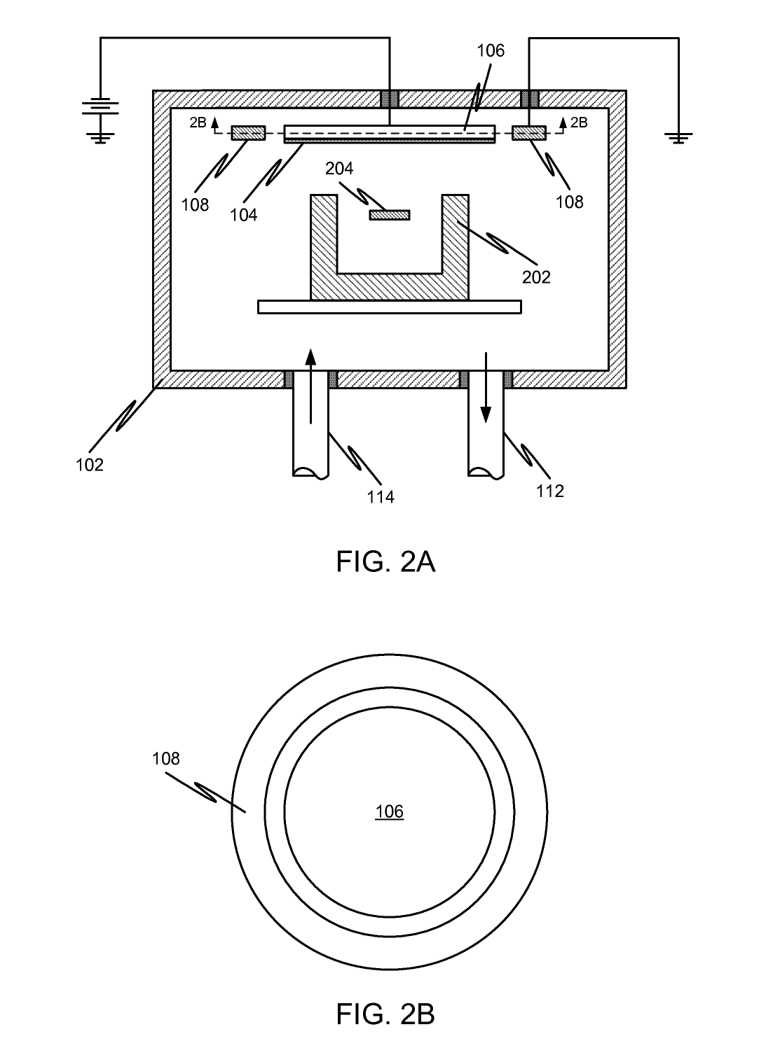

FIG. 2A illustrates an embodiment of a sputtering system. The reaction chamber 102 has a cathode 106 located at one end thereof. Located at the same end of the reaction chamber 102 is an anode 108. The anode 108 and the cathode 106 may be arranged adjacent to each other at the same end of the reaction chamber 102, as shown. For example, the cathode 106 may be a disk-shaped electrode and the anode 108 may be an annular-shaped electrode surrounding the cathode 106. The cathode 106 can be centered in the interior region of the anode 108, as shown diagrammatically in FIG. 2B. In such a configuration, the cathode may have a diameter of, for example, approximately 12.7 cm. The anode may have an inner diameter of, for example, approximately 14 cm and an outer diameter of, for example, approximately 16.6 cm. The assembly of cathode and anode would thus have a gap of approximately 0.65 cm therebetween extending around the circumference. Of course, other shapes and configurations for the anode 108 and the cathode 106 are also possible according to one or more contemplated embodiments. Attached to (or integrated with) the cathode is a target 104 of material to be sputtered onto a sample 204. A surface of the anode 108 can be coplanar with a surface of the cathode 106, as illustrated in FIG. 2A. Alternatively, the surface of the anode can be spaced from a surface of the cathode or, for example, coplanar with a sputtering surface of the target 104.

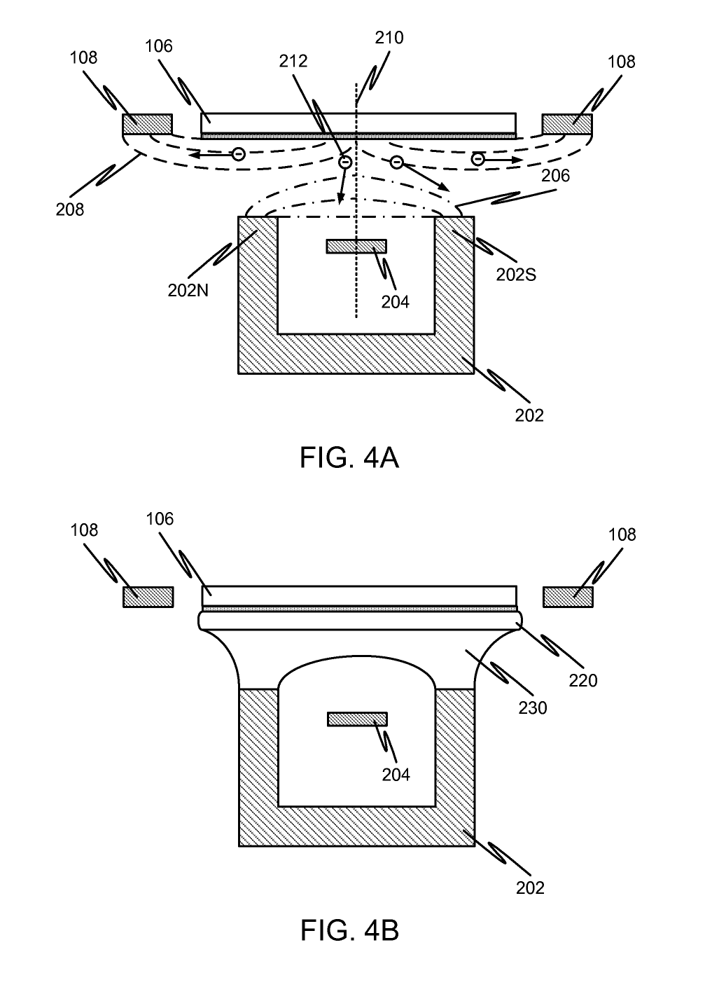

After evacuation, the reaction chamber 102 can be filled with filtered pure gas, for example, nitrogen, to a low pressure, such as 100 mTorr. In an embodiment, a nitrogen gas supply is provided with a 0.1 micron filter, such as a nuclear pore filter, to provide the filtered pure gas to the reaction chamber 102. With reference to FIG. 4A and FIG. 4B, application of a voltage difference between the anode 108 and the cathode 106 results in an electric field being generated therebetween. For example, a high negative potential (e.g., between −120V and −600V) can be applied to the cathode 106 while anode 108 is grounded. Examples of electric field lines 208 are shown as dashed lines in FIG. 4A. Note that only a sample of electric field lines has been illustrated for clarity. The electric field 208 accelerates free electrons toward the anode 108. The free electrons collide with nitrogen atoms in the reaction chamber 102 to generate ions and secondary electrons 212. The ions (not shown) are accelerated toward the cathode 106 and impact the target 104 to effect sputtering of material therefrom. Ions and secondary electrons 212 also collide with other gas molecules. The resulting avalanche of collisions and electron-ion formation creates plasma 230 between the anode 108 and cathode 106, as shown in FIG. 4B. Not that the element 220 represents the cathode dark space between the cathode 106/target 104 and the plasma 230. Although regions of plasma 230 and dark space 220 have been demarcated with lines in FIG. 4B, it will be appreciated by one of ordinary skill in the applicable that these lines arts are for illustration purposes only and that actual boundaries for the plasma and dark space may be less definitive.

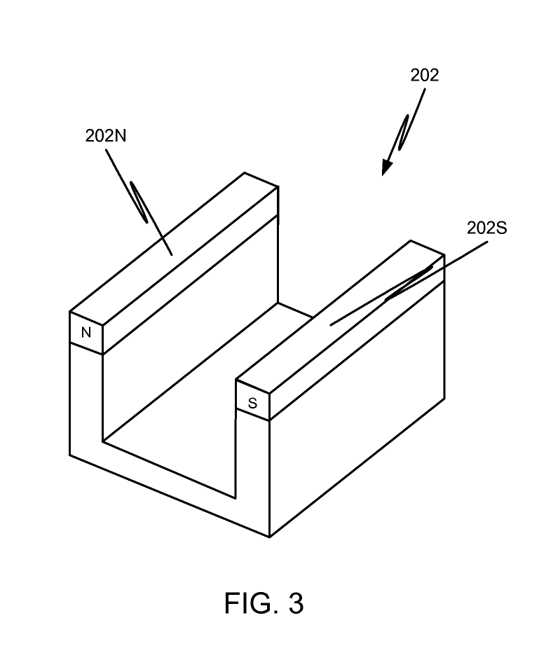

A U-shaped magnet 202 can be arranged in the reaction chamber 102 facing the cathode 106. For example, the magnet 202 can be spaced from the cathode and located within a maximum lateral extent of the cathode in a direction parallel to a sputtering surface of the cathode 106 or target 104. The sample 204 can be positioned at a sample location between the magnet 202 and the cathode 106. The U-shaped magnet 202 can have an open end facing toward the cathode 106 and a closed end away from the cathode 106. The shape of the magnet 202, as shown in FIG. 3, is such that both poles (i.e., the north pole 202N and the south pole 202S) of the magnet are separated at the open end and face the target 104.

Location of magnet 202 in reaction chamber 102 introduces a magnetic field which interacts with the sputtering process to reduce and/or minimize the number of secondary electrons incident on sample 204 from the sputtering process. Examples of magnetic field lines 206 extending between the north pole 202N and the south pole 202S of the magnet 202 are illustrated as dash-dot lines in FIG. 4A. Note that only a sample of magnetic field lines has been illustrated for clarity. The magnetic field of magnet 202 is arranged such that at least a portion of the magnetic field lines 206 have a component which is perpendicular to a surface normal 210 of the target 104 in a region between the sample 204 and the cathode 106. The magnetic field 206 thus interacts with secondary electrons 212 in plasma 230 and secondary electrons 212 travelling toward sample 204 from plasma 230. The component of the magnetic field 206 perpendicular to a velocity direction of the secondary electrons 212 exerts a force on the moving charge. This force is perpendicular to both the velocity of the electron 212 and the magnetic field component, thereby deflecting the electrons 212 away from the sample 204.

The magnetic field 206 also serves to distort the formation of plasma 230, as shown in FIG. 4B, away from sample 204, thereby protecting the sample 204 from secondary electrons 212 that may also escape from any electron confinement afforded by the electric field 208 due to the coplanar arrangement of the cathode 106 and the anode 108. The magnet 202 is located at a side of plasma 230 opposite to that of the cathode 106. Moreover, at least one pole of magnet 202 can be arranged between the sample 204 and the plasma 230 (and thereby also the target 104) in a direction perpendicular to a sputtering surface of the target 104. The magnetic field lines 206 may also cause some secondary electrons to impinge on poles 202N and 202S, thereby extending the plasma region at least to some extent to the top plane 202a of magnet 202. Since the magnetic field generated by the U-shaped magnet serves to deflect secondary electrons from the plasma away from the sample 204, the temperature increase of the sample 204 can be reduced and/or mitigated to minimize thermal damage of the sample.

The U-shaped magnet 202 may be any type of permanent magnet with sufficient magnetic field strength to deflect at least some (but preferably at least a majority, and still more preferably at least most) of the secondary electrons that would normally be incident on the sample 204 under a sputtering operation performed without the magnet 202. For example, the U-shaped magnet may be an Alnico magnet with a magnetic field in the range of 12000 gauss. The magnet may have a width at its bottom edge (opposite the two magnetic poles of FIG. 3) of, for example, approximately 4.4 cm. Between the bottom and the top edges of the poles, the magnet may have a height of, for example, approximately 3.2 cm. The top edge of each pole may be approximately 1.3 cm across. Thus, the width of the open region between the north pole 202N and the south pole 202S may be, for example, approximately 1.8 cm.

The selection of an appropriate magnet for use in a sputtering system can be dependent on a variety of factors, including sputtering system configuration, ionization currents, and operating conditions, such as gas pressure. Accordingly, other shapes, sizes, and magnetic field strengths can be employed for different systems to effect the deflection of secondary electrons as disclosed herein. Although permanent magnets are preferred for their simplicity, other mechanisms may be used to generate the appropriate magnetic fields adjacent to the plasma, such as electromagnets. In addition, it is contemplated that the magnet should be composed of materials that exhibit minimal outgassing and particle emissions under vacuum conditions so as not to interfere with the evacuation of the reaction chamber and subsequent sputtering operations. It should also be appreciated that the sizes and component specifications for the sputtering system discussed above are exemplary in nature. Other sizes, shapes, and configurations are also possible according to one or more contemplated embodiments. For example, the size of the cathode, anode, reaction chamber, magnet, etc., may be scaled to accommodate larger and/or more samples.

The target 104 can be made of, for example, gold-palladium so as to effect deposition of a gold-palladium film onto sample 204. The gold-palladium may be 40% gold and 60% palladium, based on weight. It should be appreciated that other target material compositions are also possible according to one or more contemplated embodiments.

As discussed above, the disclosed sputtering technique is especially applicable for coating thermally sensitive or relatively fragile specimens, such as biological samples and gels. Biological samples can include, for example, soft tissue samples, such as a cancer cells. Non-conductive specimens, such as biological samples, may require a conductive coating to allow for viewing by microscopic imaging equipment, such as a scanning electron microscope (SEM). While conventional approaches such as thermal evaporation and conventional sputtering are available for robust substrates and systems, soft tissue biological specimens may exhibit thermal denaturing of the cell membrane at temperatures in excess of 55° C. By using the disclosed technique, temperatures lower than the denaturing temperature can be attained during the sputtering process, thus making sputtering accessible to samples which typically have not successfully undergone sputtering. However, the disclosed techniques are not limited to thermally sensitive or biological samples. Rather, the disclosed techniques are applicable to specimens that are able to undergo traditional sputtering with no or minimal damage as well. Such specimens may benefit from more uniform coating deposition or coating characteristics when the disclosed sputtering process is employed.

With respect to biological samples, as long as the temperature of the sample is maintained less than the denaturing temperature, the specimen may survive the sputtering process with minimal damage. The biological specimen or other thermally sensitive specimen can thus be located at any position within the reaction chamber that results in a sputtering temperature less than the denaturing temperature. The location of the specimen can also take into account film deposition characteristics in addition to sputtering temperature of the sample. Such film deposition characteristics can include film uniformity, conformal coating, and deposition speed. For example, the sample 204 may be located in the open region of U-shaped magnet 202 between the two poles, but spaced lower than the top plane 202a of the magnet 202.

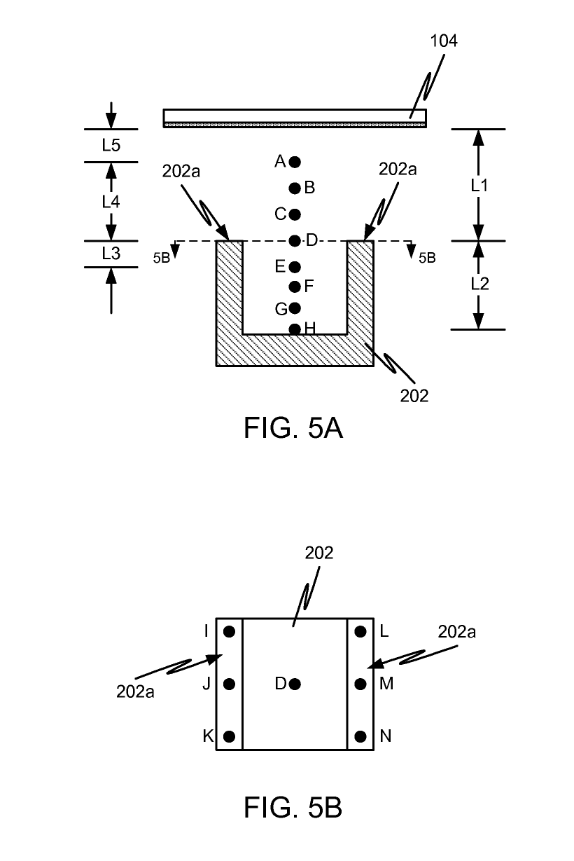

In a system constructed as shown in FIG. 2A, temperature readings were taken with and without magnet 202 in place at different ionization currents (5 mA, 10 mA, and 15 mA) to ascertain the impact of the introduced magnetic field on sample temperature during sputtering. FIG. 5A shows the locations A-H of temperature readings taken along a center line of the magnet 202 of the system of FIG. 2A, while FIG. 5B shows the locations D and I-N of temperature readings taken along the top plane 202a of the magnet 202. To measure temperature, thermocouples at each location were periodically sampled during an actual sputtering run. The data provided herein is an average of data collected over several runs.

Magnet 202 was positioned at a distance L₁=2.5 cm from the target 104. Points A-D were located in equal intervals of 0.5 cm between a distance L₅=1 cm from the target and a distance L₁=2.5 cm from the target. Thus, points A-D extended over a length L₄ of 1.5 cm. Point D was located on a top plane 202a of the magnet 202 and centered in the open region. Points E-H were located in equal intervals of 0.5 between a distance L₃=0.25 cm from the top plane 202a and a distance L₂=1.75 cm from the top plane 202a of the magnet 202. Points I, K, L, and N were located on the top plane 202a of the magnet at each respective corner. Points J and M were coplanar with point D on the top plane 202a and centered at each pole.

Table 1 shows temperature readings obtained for each of the locations after 60 seconds of sputtering. Table 2 shows temperature readings obtained for location E after 60 seconds of sputtering with and without magnet 202 in FIG. 2A. Table 3 shows temperature readings at the top plane 202a of magnet 202 after 60 seconds of sputtering.

As is evident from the data in Table 2, the addition of the magnet 202 results in a significant temperature reduction when compared to the sputtering system without the magnet 202. Moreover, the data illustrates that a variety of sputtering temperatures are available depending on location in the reaction chamber with respect to the magnet 202 and depending on ionization current. By judicious selection of sample position and ionization current, one can sputter samples which may have different temperature limitations. Accordingly, it is possible to sputter sensitive samples, such as soft tissue biological specimens, that were heretofore susceptible to thermal damage when sputtered by conventional systems.

TABLE 1
Temperatures at various points (FIG. 5A) in reaction
chamber of a sputtering system after 60 seconds with the magnet
202 in place.

| | Ionization Current (mA) | | |
|---|---|---|---|
| Position | 5 | 10 | 15 |
| A | 60° C. | 100° C. | 101° C. |
| B | 52° C. | 72° C. | 80° C. |
| C | 46° C. | 62° C. | 74° C. |
| D | 40° C. | 56° C. | 66° C. |
| E | 38° C. | 50° C. | 60° C. |
| F | 32° C. | 40° C. | 52° C. |
| G | 27° C. | 35° C. | 43° C. |
| H | 25° C. | 30° C. | 34° C. |

TABLE 2
Temperatures at location E (FIG. 5A) in reaction chamber of
a sputtering system after 60 seconds with and without the magnet
202 in place.

| | Ionization current (mA) | | |
|---|---|---|---|
| | 5 | 10 | 15 |
| Position E with magnet | 38° C. | 50° C. | 60° C. |
| Position E without magnet | 72° C. | 105° C. | 138° C. |

TABLE 3
Temperatures at top plane 202a of magnet 202 (FIG. 5B) in
reaction chamber of sputtering system after 60 seconds at an
ionization current of 15 mA.

| | Positions | | | | | | |
|---|---|---|---|---|---|---|---|
| | D | I | J | K | L | M | N |
| Temperature | 66° C. | 100° C. | 108° C. | 95° C. | 95° C. | 108° C. | 100° C. |

As would be expected, the measured temperatures increase with increasing ionization current. Increasing ionization current also results in higher deposition rates. Thus, it is contemplated that a user can balance between higher deposition rates and temperature limitations in determining operating parameters (e.g., ionization current) for coating a particular sample. Ionization current is related to the applied voltage on the cathode, with greater negative voltages resulting in greater ionization currents. Further, the position of the sample within the reaction chamber and relative to the magnet can be balanced with control of the ionization current to control deposition characteristics without exceeding sample temperature limitations.

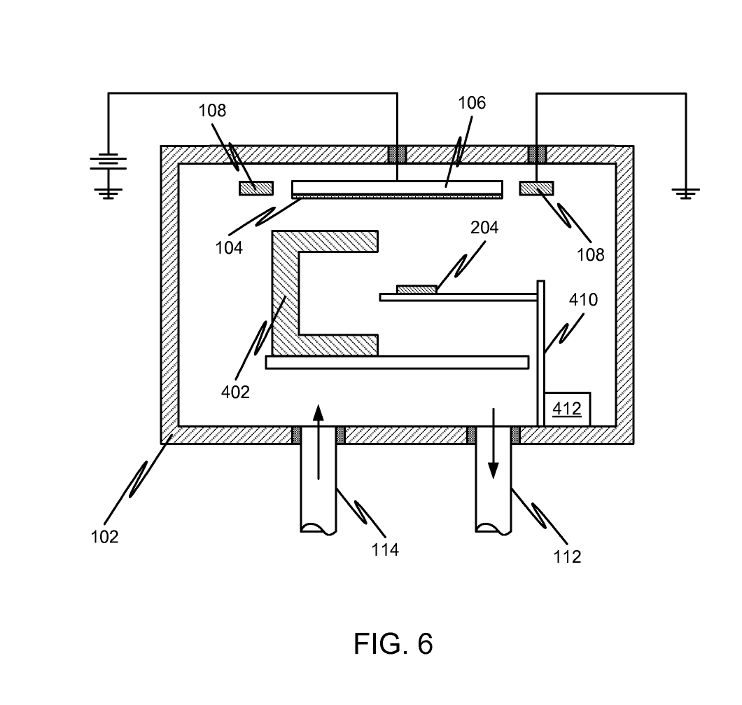

The orientation of the magnet can also have an impact on the temperature profile in the reaction chamber. For example, by rotating the U-shaped magnet 202 by 90° in a clockwise direction (in effect, resulting in a C-shaped orientation), an increased portion of the reaction chamber can be made relatively low temperature as compared to the orientation illustrated in FIG. 2A. FIG. 6 shows a schematic diagram of an embodiment of sputtering system incorporating a magnet with such an orientation.

The configuration of the reaction chamber 102, anode 108, cathode 106, and target 104 in the embodiment of FIG. 6 is the same as that of the embodiment of FIG. 2A. Operation of the system to effect sputtering is thus similar to that of the embodiment of FIG. 2A and will not be repeated here. However, in contrast to the embodiment of FIG. 2A, the U-shaped magnet 402 is arranged such that one pole of the magnet 402 (e.g., pole 402N) is closer to the target 104 than the other pole of the magnet 402 (e.g., pole 402S). In other words, U-shaped magnet 402 has an open area between the two poles which does not face the cathode 104, so as to have a C-shaped orientation. The sample 204 is located at some point adjacent the magnet and facing the cathode 104.

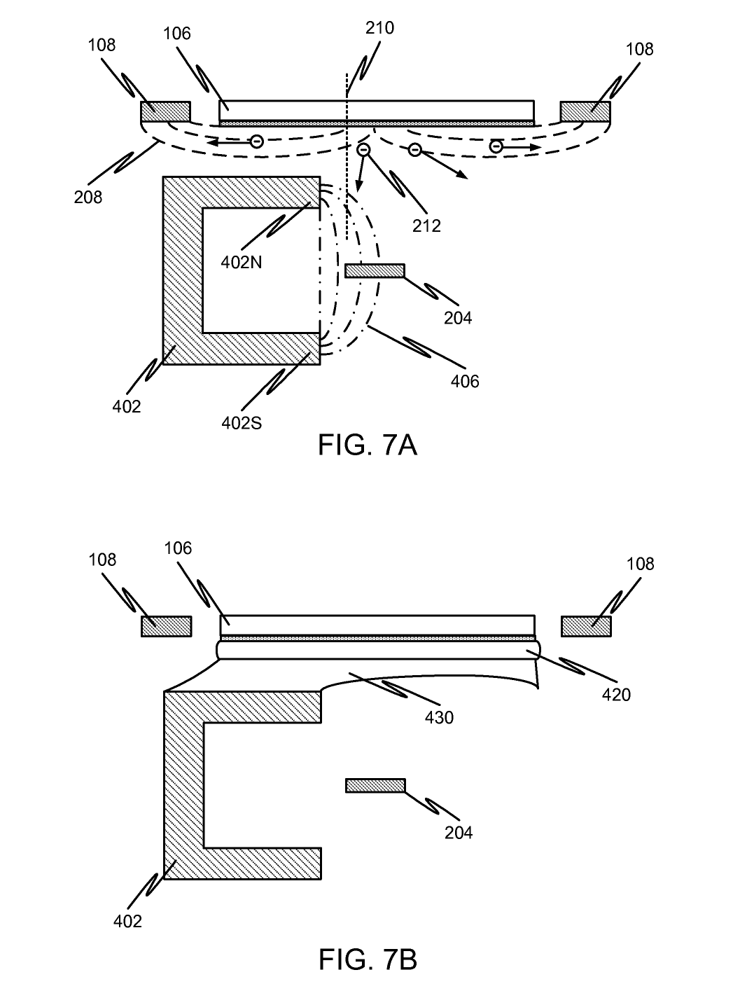

With reference to FIG. 7A and FIG. 7B, the location of magnet 402 in reaction chamber 102 introduces a magnetic field which interacts with the sputtering process to reduce and/or minimize the number of secondary electrons incident on sample 204 from the sputtering process. Examples of magnetic field lines 406 extending between the north pole 402N and the south pole 402S of the magnet 402 are illustrated as dash-dot lines in FIG. 7A. Note that only a sample of magnetic field lines has been illustrated for clarity. The magnetic field of magnet 402 is arranged such that at least a portion of the magnetic field lines 406 have a component which is perpendicular to a surface normal 210 of the target 104 in a region between the sample 204 and the cathode 106. The magnetic field 406 thus interacts with secondary electrons 212 in plasma 430 and secondary electrons 212 travelling toward sample 204 from plasma 430. Note that the element 420 represents the cathode dark space between the cathode 106/target 104 and the plasma 430. Although regions of plasma 430 and dark space 420 have been demarcated with lines in FIG. 7B, it will be appreciated by one of ordinary skill in the applicable arts are for illustration purposes only and that actual boundaries for the plasma and dark space regions may be nebulous.

As previously discussed, the component of the magnetic field 406 perpendicular to a velocity direction of the secondary electrons 212 exerts a force on the moving charge, thereby deflecting the electrons 212 away from the sample 204. The magnetic field 406 also serves to distort the formation of plasma 430 as shown in FIG. 7B away from sample 204, thereby protecting the sample 204 from secondary electrons 212 that may escape from any electron confinement afforded by the electric field 208 due to the coplanar arrangement of the cathode 106 and the anode 108. The magnet 402 is located at a side of plasma 430 opposite to that of the cathode 106. Moreover, at least one pole of magnet 402 (e.g., pole 402N) can be arranged between the sample 204 and the plasma 430 (and thereby also the target 104) in a direction perpendicular to a sputtering surface of the target 104. The magnetic field lines 406 may also cause some secondary electrons to impinge on the side surface of the magnet 402 closest to the plasma 430, thereby extending the plasma region at least to some extent to the magnet 402.

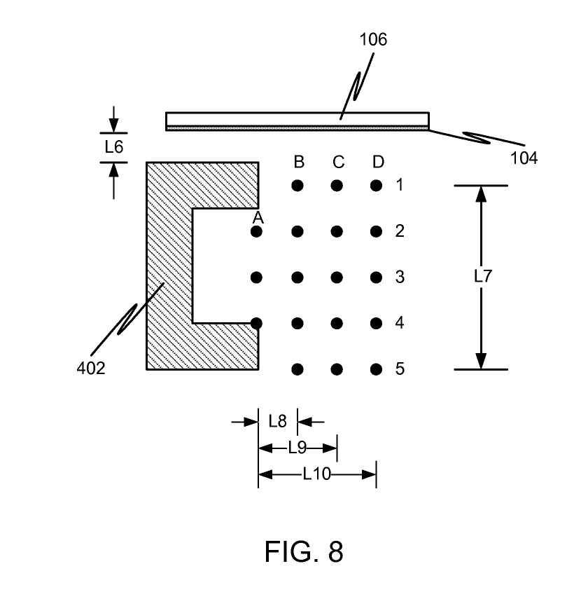

In the sputtering system of FIG. 6, temperature readings were taken with the magnet in place at different ionization currents (5 mA, 10 mA, and 15 mA) to ascertain the impact of the introduced magnetic field on sputtering temperature. FIG. 8 shows the location of temperature readings A2-A4 and B1-D5 adjacent to the magnet 402 of FIG. 6. To measure the temperature, thermocouples at each location were periodically interrogated during an actual sputtering run.

The magnet 402 was positioned at a distance L₆=0.5 cm from the cathode 104. The columns A-D were located in equal intervals of 1 mm. Column A was located at the right edge of the U-shaped magnet 402. Column B was located at a distance L₈=1 mm from the right edge. Column C was located at a distance L₉=2 mm from the right edge. Column D was located at a distance L₁₀=3 mm from the right edge. Rows 1-5 were located in equal intervals of 1 cm. Row 5 was located at the bottom edge of the magnet 402. Row 1 was located at a distance of L₇=4 cm from the bottom edge. Note that column A did not have temperature readings for rows 1 and 5, as these were located in the magnet 402.

Tables 4-5 show temperature readings obtained for each of the locations after 60 seconds of sputtering. The data shown in the tables is an average of data collected over several runs.

TABLE 4
Temperatures at various points (FIG. 8) in reaction chamber of a
sputtering system after 60 seconds with magnet 402 in place.

| | Ionization current (mA) | | | | | | | | |
|---|---|---|---|---|---|---|---|---|---|
| | 5 | | | 10 | | | 15 | | |
| Location | B | C | D | B | C | D | B | C | D |
| 1 | 65° C. | 92° C. | 120° C. | 58° C. | 72° C. | 82° C. | 53° C. | 60° C. | 67° C. |
| 2 | 40° C. | 48° C. | 56° C. | 40° C. | 50° C. | 58° C. | 43° C. | 51° C. | 56° C. |
| 3 | 33° C. | 37° C. | 42° C. | 33° C. | 35° C. | 42° C. | 33° C. | 37° C. | 42° C. |
| 4 | 32° C. | 34° C. | 38° C. | 33° C. | 35° C. | 38° C. | 32° C. | 34° C. | 35° C. |
| 5 | 27° C. | 28° C. | 29° C. | 28° C. | 29° C. | 30° C. | 28° C. | 29° C. | 30° C. |

TABLE 5
Temperatures at various points (FIG. 8) in reaction chamber
of a sputtering system after 60 seconds with magnet 402 in place.

| | |
|---|---|
| Location | Ionization current (mA) |

| Column | Row | 5 | 10 | 15 |
|---|---|---|---|---|
| A | 2 | 34° C. | 37° C. | 42° C. |
| A | 3 | 30° C. | 33° C. | 35° C. |
| A | 4 | 32° C. | 34° C. | 35° C. |

Since the magnetic field generated by the U-shaped magnet serves to deflect secondary electrons from the plasma away from the sample 204, the temperature increase of the sample 204 can be reduced and/or mitigated to minimize thermal damage of the sample. The magnetic field generated by the magnet 402 can act to minimize temperature of a sputtered sample in a greater portion of the reaction chamber 102. Thus, not only can a temperature increase of the sample 204 be averted, but a user may also be able to arrange the sample 204 at a greater number of positions within the reaction chamber or have a sample larger than would fit between the poles of magnet 402. Alternately, a greater number of samples may be processed at the same time.

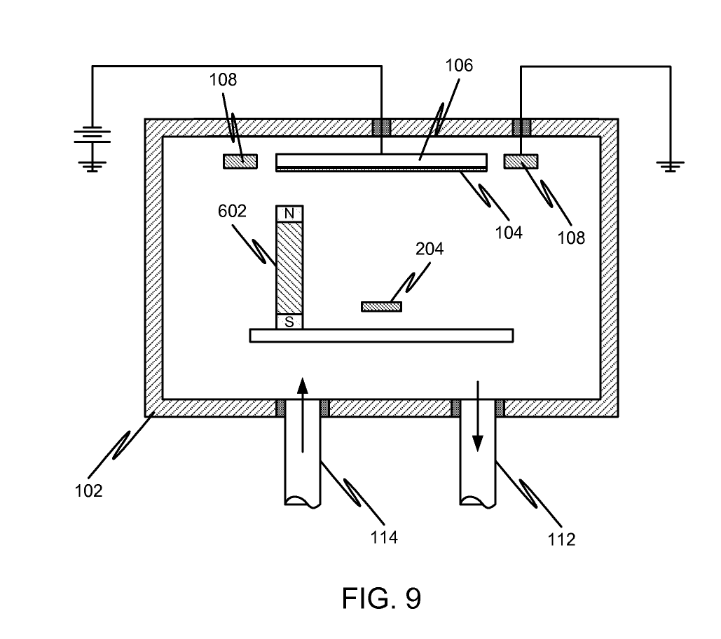

While the embodiments described above employ a U-shaped magnet, other shapes and configurations for the magnet used in the sputtering system reaction chamber are also possible according to one or more contemplated embodiments. For example, the U-shaped magnet can be replaced with a magnet having a different shape or magnetic field configuration. With reference to FIG. 9, an alternative configuration for a magnet used in the sputtering system is shown. In particular, the U-shaped magnet is replaced with a bar magnet 602 arranged in the reaction chamber 102 with one magnetic pole (N) proximal to the cathode 106 and another magnetic pole (S) distal to the cathode 106. The configuration of the reaction chamber 102, anode 108, cathode 106, and target 104 in the embodiment of FIG. 9 is the same as that of the embodiments of FIG. 2A and FIG. 6. Accordingly, operation of the system to effect sputtering is similar to that previously described and will not be repeated here.

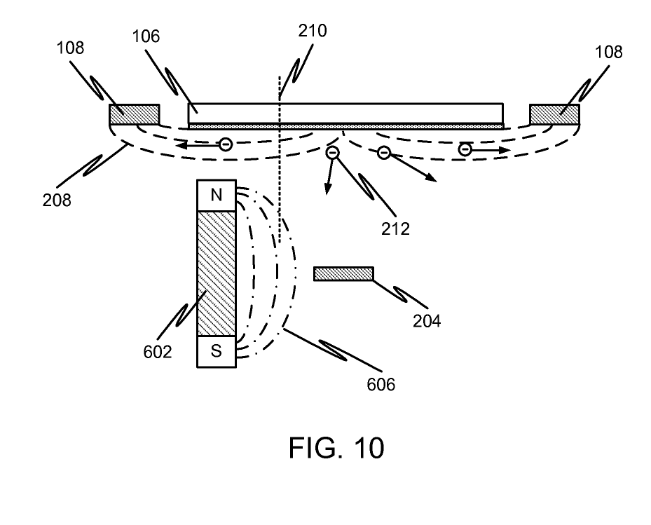

With reference to FIG. 10, location of magnet 602 in reaction chamber 102 introduces a magnetic field which interacts with the sputtering process to reduce and/or minimize the number of secondary electrons incident on sample 204 from the sputtering process. Examples of magnetic field lines 606 extending between the poles of the magnet 602 are illustrated as dash-dot lines in FIG. 10. Note that only a sample of magnetic field lines has been illustrated for clarity. The magnetic field of magnet 602 is arranged such that at least a portion of the magnetic field lines 406 have a component which is perpendicular to a surface normal 210 of the target 104 in a region between the sample 204 and the cathode 106. The magnetic field 606 thus interacts with secondary electrons 212 in the plasma and secondary electrons 212 travelling toward sample 204 from plasma. Similar to the previously described embodiments, the component of the magnetic field 606 perpendicular to a velocity direction of the secondary electrons 212 exerts a force on the moving charge, thereby deflecting the electrons 212 away from the sample 204. The magnetic field 606 may also serve to distort the formation of plasma away from sample 204, thereby protecting the sample 204 from secondary electrons 212 that may escape from any electron confinement afforded by the electric field 208 due to the coplanar arrangement of the cathode 106 and the anode 108.

The magnet 602 can be located at a side of plasma opposite to that of the cathode 106. Moreover, at least one pole of magnet 602 can be arranged between the sample 204 and the plasma in a direction perpendicular to a sputtering surface of the target 104. Since the magnetic field generated by the bar magnet serves to deflect secondary electrons from the plasma away from the sample 204, the temperature increase of the sample 204 can be reduced and/or mitigated to minimize damage of the sample.

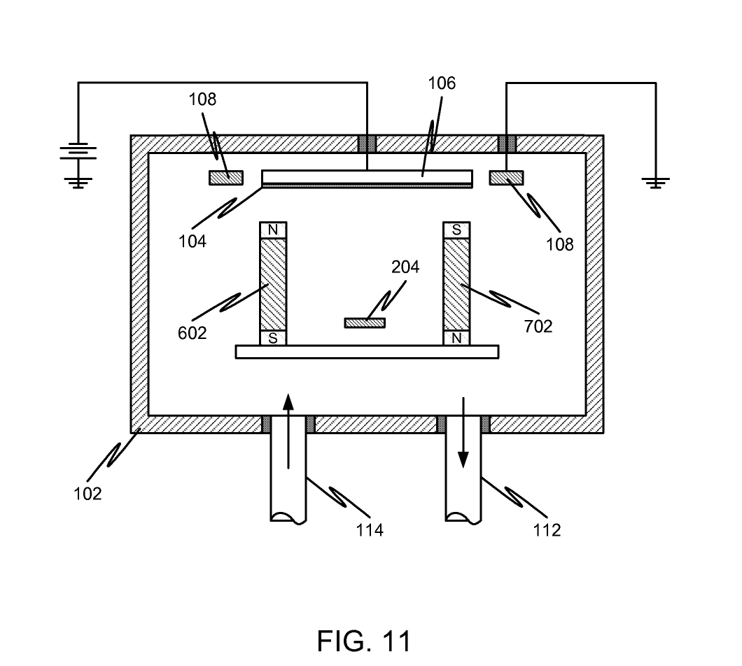

With reference to FIG. 11, yet another alternative for providing a magnet in a sputtering system to deflect secondary electrons from a sample is shown. A first bar magnet 602 and a second bar magnet 702 are located on opposite sides of the reaction chamber 102. In such a configuration, the magnets 602, 702 may be arranged such that opposite poles of the magnets are arranged at the same orientation with respect to the target 104. That is, the first magnet 602 may have a north pole proximal to the target 104 while the second magnet 702 may have a south pole proximal to the target 104. The configuration of the reaction chamber 102, anode 108, cathode 106, and target 104 in the embodiment of FIG. 11 is the same as that of the embodiments of FIG. 2A, FIG. 6, and FIG. 9. Accordingly, operation of the system to effect sputtering is similar to that previously described and will not be repeated here.

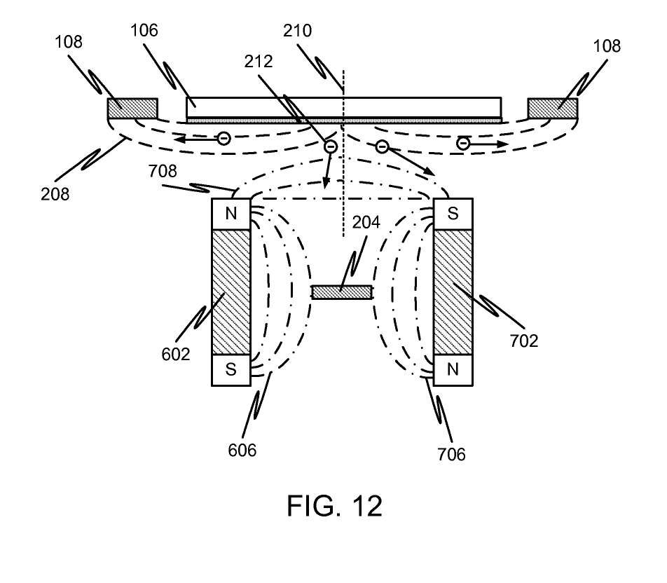

With reference to FIG. 12, location of magnets 602 and 702 in reaction chamber 102 introduces a magnetic field which interacts with the sputtering process to reduce and/or minimize the number of secondary electrons incident on sample 204 from the sputtering process. Examples of magnetic field lines 606, 706 extending between the poles of magnets 602, 702, respectively, are illustrated as dash-dot lines in FIG. 12. Since the magnets 602, 702 are arranged such that their opposite poles are at the same orientation, the magnetic field also extends between the opposite poles between the magnets. Examples of magnetic field lines 708 extending between the opposite poles of magnets 602, 702 are illustrated in FIG. 12. Note that only a sample of magnetic field lines has been illustrated for clarity. The magnetic fields of magnets 602, 702 is arranged such that at least a portion of the magnetic field lines 606, 706, 708 have a component which is perpendicular to a surface normal 210 of the target 104 in a region between the sample 204 and the cathode 106. The magnetic fields 606, 706, 708 thus interact with secondary electrons 212 in the plasma and secondary electrons 212 travelling toward sample 204 from plasma. Similar to the previously described embodiments, the component of the magnetic fields 606, 706, 708 perpendicular to a velocity direction of the secondary electrons 212 exerts a force on the moving charge, thereby deflecting the electrons 212 away from the sample 204. The magnetic fields 606, 706, 708 may also serve to distort the formation of plasma away from sample 204, thereby protecting the sample 204 from secondary electrons 212 that may also escape from any electron confinement afforded by the electric field 208 due to the coplanar arrangement of the cathode 106 and the anode 108.

The magnets 602, 702 can be located at a side of plasma opposite to that of the cathode 106. Moreover, at least one pole of each magnet can be arranged between the sample 204 and the plasma in a direction perpendicular to a sputtering surface of the target 104. Since the magnetic field generated by the bar magnets serves to deflect secondary electrons from the plasma away from the sample 204, the temperature increase of the sample 204 can be reduced and/or mitigated to minimize thermal damage of the sample.

It is also contemplated that the sample can be arranged at different locations within a given setup to take advantage of different sputtering temperatures. For example, an adjustable holder may be included in the sputtering system to move the sample to various sample locations within the interior volume of the reaction chamber. Such an adjustable holder can take various forms. For example, an adjustable holder 410 is illustrated schematically in FIG. 6. A platform may support the sample 204 in spaced relationship from the magnet 402 and the target 104. The platform may be movable in three dimensions to allow precise control of the location of the sample with respect to the magnet 402 and the target 104. Alternatively, the platform may be movable in less than three dimensions. An actuator 412 can be provided within the interior of the reaction chamber 102 to control motion of the adjustable holder 410. Alternatively, the actuator 412 can be provided external to the reaction chamber 102. A controller can be integrated with the actuator 412 to provide automated or semi-automated control of sample positioning. The controller may be responsive to user input or to automated instructions from, for example, a computer program. In still another alternative, the adjustable holder 410 can be manually adjustable. Such manual adjustment may occur prior sealing of the reaction volume 102. Alternatively, a mechanism may be provided external to the reaction volume 102 that allows manual adjustment of the holder 410 by a user once the reaction chamber has been sealed.

In general, the magnet is located in a spaced relationship from the target but within the reaction chamber. The sample is located between a maximum lateral extent of the target in a direction parallel to a sputtering surface of the target and facing the target so as to receive material sputtered from the target. The magnet can also be located between a maximum lateral extent of the target and/or anode in a direction parallel to the sputtering surface of the target. It is contemplated that the magnet(s) can be arranged proximal to the sample so as to provide sufficient protection to the sample from electron bombardment. Further, the magnet(s) may be arranged such that at least a portion of its magnetic field lines have a component which is perpendicular to the flow of secondary electrons toward the sample. While orientations have been illustrated with magnetic field lines that may run parallel to the flow of secondary electrons at certain locations within the reaction volume, it is noted that at least a portion of the magnetic field lines have a component that is perpendicular to the secondary electron flow toward the sample during sputtering.

In embodiments, means for holding a sample can be provided to position a biological specimen or other samples within a sputtering system reaction chamber. Means for altering secondary electron flow may be included within the reaction chamber. Such means for altering secondary electron flow may be configured to deflect secondary electrons generated during a sputtering process away from the sample. The means for altering secondary electron flow may include magnetic means, such as magnet 202, magnet 402, magnet 602, magnet 702, or any combination thereof effective to prevent secondary electrons from impacting the biological specimen. The sample can be placed proximal to the means for altering secondary electron flow on a side of plasma generated during sputtering opposite to a side of the plasma at which the target is located. Application of an appropriate electric field between the target and the anode in the presence of a low-pressure gas results in sputtering of the target material onto the biological specimen. Proximal, as used herein, is determined by the effect of the magnetic field of the means for altering secondary electron flow. Greater magnetic fields would evidently allow a sample to be located farther from the means for altering secondary electron flow than comparatively weaker magnetic fields.

In embodiments, the optimal position for the biological specimen can be determined by temperature sampling during a test run of the sputtering system. During said test run, various positions may be sampled for deposition rate and temperature with the magnetic means in place to determine an optimal balance between sputtering deposition rate and temperature. For biological specimens, the temperature at the surface of the specimen may be minimized and, preferably, kept below 55° C. These biological specimens may include cancer cells, viruses, bacteria, tissue samples, or any known biological specimen which can benefit from the low temperature sputtering method. Further, the systems and methods disclosed herein may be applied to other temperature sensitive samples outside of the biological realm, such as gels, semiconductors devices, MEMS devices, polymers, plastics, and the like.

In embodiments, a sputtering system can include a target and an anode located in a reaction chamber. The target can be held at a high negative potential relative to the anode during a sputtering process. A magnet may be arranged in the reaction chamber so as to be adjacent to the target in the direction of sputtering but spaced from a sputtering surface of the target. During the sputtering process, secondary electrons can progress from the target in the sputtering direction toward a sample to be sputtered arranged in the reaction chamber. The magnet is arranged so as to deflect secondary electrons generated by the sputtering process away from the sputtering direction. Thus, material from the target is deposited on the sample while reducing electron bombardment thereof.

In an aspect, the magnet may be a permanent magnet. In another aspect, the magnet may be an electromagnet. In yet another aspect, the magnet may be a U-shaped magnet, a C-shaped magnet, or horseshoe shaped magnet. In yet another aspect, the magnet may be a bar-shaped magnet. In yet another aspect, the magnet may be two bar magnets.

In still another aspect, the magnet may be a U-shaped magnet arranged with an open region between the two poles of the magnet facing the target. The sample may be located between the two poles of the magnet outside of the open region. In another aspect, the sample may be located between the two poles of the magnet within the open region. In another aspect, the sample may be located in the open region between the two poles and co-planar with the end surfaces of the two poles.

In still another aspect, the magnet may be a U-shaped magnet arranged with one of the poles of the magnet oriented closer to the target than the other pole. The sample may be located between the target and the other pole of the magnet in a region outside of an open region between the two poles of the magnet.

In another aspect, a low-pressure ionizable gas is introduced into the reaction chamber to form plasma for effecting sputtering. In yet another aspect, the ionizable gas is nitrogen. Alternatively, the ionizable gas is xenon or argon.

In still another aspect, the ionization current for sputtering is less than or equal to 15 mA. In yet another aspect, the ionization current is less than or equal to 10 mA. In still another aspect, the ionization current is less than or equal to 5 mA. In another aspect, the voltage applied to the target or cathode is between −120 V and −600 V, inclusive.

In embodiments, a sputtering system can have a target and an anode located in a reaction chamber. Material from the target is deposited on a sample to be sputtered. A magnet can be located in the reaction chamber such that at least a portion of the magnetic field lines of the magnet have a component that is perpendicular to the direction of sputtered material from the target.

In embodiments, a sputtering system can have a disk-shaped target and an annular anode located in a reaction chamber. The annular anode and the target can be substantially coplanar. The target can be centered within the anode. A magnet may be opposed to the target in a spaced relationship. Plasma may be generated in the space between the magnet and the target during sputtering by application of an electric field between the anode and the target.

In embodiments, a sputtering system can have a permanent magnet and a target located in a reaction chamber. The target and anode can be arranged at a first end of the reaction chamber so as to face a second end of the reaction chamber. The magnet can be positioned within the reaction chamber between the target and the second end of the reaction chamber. Plasma can be formed during sputtering between the target and the magnet. The sample can be located between the second end of the reaction chamber and the plasma.

In embodiments, a method for sputtering a sample can include providing a magnet in a reaction chamber of a sputtering system and placing a sample proximal to the magnet. The method can also include sputtering material from a target onto the sample by applying an electric field between a target and an anode.

In an aspect, the step of providing can include providing a magnet so as to alter a direction of secondary electrons such that secondary electrons do not impact the sample. In another aspect, the sample is a biological specimen. In yet another aspect, the step of providing can include orienting the magnet in the reaction chamber to face the target such that plasma can be generated in a space between the target and the magnet during sputtering. The positions of the magnet and the sample can be such that that the temperature of the sample is below 55° C. during the sputtering with an ionization current less than 15 mA. In still another aspect, the step of providing can include positioning a magnet in the reaction chamber at a side of a plasma generated during sputtering which is opposite to a side of the plasma at which the target is disposed, such that at least a portion of the magnetic field lines of the magnet have a component which is perpendicular to a direction of sputtering on the sample.

In yet another aspect, the specimen may be a cancer cell, virus, bacteria, or tissue sample. In yet another aspect, the specimen may be a thermally sensitive sample. In yet another aspect, during the sputtering step, the temperature does not exceed 55° C.

In embodiments, a method for sputtering a thermally sensitive sample can include providing means for altering secondary electron flow toward a sample holder, the sample holder being arranged in a reaction chamber of a sputtering system, and placing the thermally sensitive sample at the sample holder in the reaction chamber, wherein said means for altering secondary electron flow substantially reduces the number of electrons incident on the surface of the thermally sensitive sample during a sputtering operation as compared to sputtering without said means for altering secondary electron flow. The method may further comprise sputtering a coating on the thermally sensitive sample by applying an electric field between a cathode and an anode so as to generate plasma.

In yet another aspect, said means for altering secondary electron flow includes magnetic means disposed opposite to the cathode. In yet another aspect, the magnetic means is a U-shaped magnet. In yet another aspect, the magnetic means is a magnet oriented such that the ends of the magnet are arranged in a plane parallel to a surface normal extending from the target to a sample location on the sample holder. In yet another aspect, the magnetic means is a magnet oriented such that the ends of the magnet are arranged in a plane perpendicular to the surface normal extending from the target to the sample location on the sample holder. In still another aspect, the magnetic means is a U-shaped magnet with both poles proximal to the generated plasma, wherein the step of placing includes placing the thermally sensitive sample between the poles of the magnet.

It is, thus, apparent that there is provided, in accordance with the present disclosure, systems and methods for low damage sputtering. Many alternatives, modifications, and variations are enabled by the present disclosure. Features of the disclosed embodiments can be combined, rearranged, omitted, etc., within the scope of the invention to produce additional embodiments. Furthermore, certain features may sometimes be used to advantage without a corresponding use of other features. Accordingly, Applicant intends to embrace all such alternatives, modifications, equivalents, and variations that are within the spirit and scope of the present invention.

1. A low-damage sputtering system comprising:
a reaction chamber having an inlet, an outlet, and an interior volume, the inlet being connected to a source of nitrogen, the outlet being connected to an evacuation device, the interior volume having a first end and an opposing second end;
a disk-shaped cathode arranged in the interior volume at the first end of the interior volume, the cathode having a surface normal which is perpendicular to a surface of the cathode having a target material thereon;
an annular anode arranged in the interior volume, the anode being substantially concentric and coplanar with the cathode;
a voltage supply configured to apply a negative DC voltage between the cathode and the anode; and
a substantially U-shaped permanent magnet arranged in the interior volume, the magnet being spaced from the cathode and located within a maximum lateral extent of the cathode in a direction parallel to said surface of the cathode,
wherein at least a portion of a magnetic field of the magnet has a component which is perpendicular to the surface normal of the cathode in a region between a sample location and the cathode.

2. The sputtering system according to claim 1, further comprising a sample holder to hold a sample to be sputtered at said sample location during sputtering of the target material onto the sample, the sample location being between the second end of the interior volume and the cathode.

3. The sputtering system according to claim 1, wherein the voltage supply is configured to apply a negative DC voltage in a range from −120V to −600V.

4. A low-damage sputtering system comprising:
a reaction chamber having an interior volume, the interior volume having a first end and an opposing second end;
a target arranged in the interior volume at the first end of the interior volume, the target having a sputtering surface facing the second end of the interior volume;
an anode arranged in the interior volume and being substantially coplanar with the target;
a voltage supply configured to apply a voltage between the target and the anode during a sputtering process;
a first magnet arranged in the interior volume, the magnet having a first pole and a second pole spaced from the first pole; and
a sample holder configured to hold a sample at a sample location between the second end of the interior volume and the target during the sputtering process,
wherein at least the first pole of the first magnet is arranged between the target and the sample location in a direction perpendicular to the sputtering surface.

5. The sputtering system according to claim 4, wherein at least the first pole of the first magnet is arranged between plasma formed during the sputtering process and the sample location in a sputtering direction, said at least first pole being adjacent to the formed plasma during the sputtering process.

6. The sputtering system according to claim 4, wherein the target is substantially disk-shaped, the anode is substantially annular-shaped, and the anode surrounds the target.

7. The sputtering system according to claim 4, wherein the first magnet is located within a maximum lateral extent of the cathode in a direction parallel to the sputtering surface of the cathode.

8. The sputtering system according to claim 4, wherein the first magnet is substantially U-shaped and both the first and second poles of the first magnet are arranged between the target and the sample location in the direction perpendicular to the sputtering surface.

9. The sputtering system according to claim 4, wherein the first magnet is substantially U-shaped and the second pole of the first magnet is arranged farther from the target than the first pole of the first magnet.

10. The sputtering system according to claim 4, wherein the first magnet is a bar magnet and the second pole of the first magnet is arranged farther from the target than the first pole of the first magnet.

11. The sputtering system according to claim 10, further comprising:
a second bar magnet arranged in the interior volume, the second bar magnet having a third pole and a fourth pole spaced from the third pole, the third pole being arranged between the target and the sample location in the direction perpendicular to the sputtering surface, the fourth pole being arranged farther from the target than the third pole of the second bar magnet,
wherein the third pole of the second bar magnet has a polarity opposite to that of the first pole of the first magnet.

12. The sputtering system according to claim 4, wherein the voltage supply is configured to apply a negative voltage in a range from −120V to −600V.

13. A method for sputtering a sample, the method comprising:
applying a DC voltage between an anode and a target in a reaction chamber so as to generate a plasma in the reaction chamber, ions from the plasma interacting with a surface of the target so as to cause ejection of material from the target in a sputtering direction toward the sample, the plasma generating secondary electrons within the reaction chamber;
providing a magnet in the reaction chamber with at least one pole of the magnet adjacent to the plasma at a side of the plasma opposite to a side of the plasma at which the target is disposed; and
positioning the sample proximal to the magnet such that a magnetic field of the magnet deflects the secondary electrons away from the sample and such that the ejected material from the target is deposited on the sample.

14. The method of claim 13, wherein the applying a DC voltage includes applying a voltage in a range from −120V to −600V.

15. The method of claim 13, wherein the applying a DC voltage results in an ionization current less than or equal to 15 mA, and the positioning the sample is such that a temperature of the sample is less than 55° C. while the ejected material from the target is deposited on the sample.

16. The method of claim 13, wherein the sample is a biological tissue sample.

17. The method of claim 13, wherein the magnet is a substantially U-shaped permanent magnet.

18. The method of claim 13, wherein the magnet is located between a maximum lateral extent of the target in a direction parallel to the surface of the target.

19. The method of claim 13, wherein the providing a magnet includes positioning the magnet such that the magnetic field thereof has a component that is perpendicular to a surface normal of the surface of the target in a region between the sample and the target.

20. The method of claim 13, wherein the target is substantially disk-shaped, the anode is substantially annular-shaped, and the anode surrounds the target.
